(19) United States
(12) Patent Application Publication
(10) Pub. No.: US 2025/0057000 A1
(43) Pub. Date: Feb. 13, 2025

(54) DISPLAY APPARATUS

(71) Applicant: Samsung Display Co., Ltd., Yongin-si (KR)

(72) Inventors: Jinsook Bang, Yongin-si (KR); Ilhoo Park, Yongin-si (KR); Jinouk Song, Yongin-si (KR); Sanghoon Yim, Yongin-si (KR); Seongjin Jeong, Yongin-si (KR)

(73) Assignee: Samsung Display Co., Ltd., Yongin-si (KR)

(21) Appl. No.: 18/670,891

(22) Filed: May 22, 2024

(30) Foreign Application Priority Data
Aug. 9, 2023 (KR) 10-2023-0104345

(51) Int. Cl. H10K 59/38; H10K 50/11; H10K 50/816; H10K 59/40; H10K 59/80

(52) U.S. Cl. CPC H10K 59/38; H10K 50/816; H10K 59/40; H10K 59/8731; H10K 50/11

(57) ABSTRACT

A display apparatus includes, a light emitting device disposed over an emission area of a substrate and emitting light of a first wavelength, and a display panel including a color filter disposed over the light emitting device, a transmittance of the color filter of light of the first wavelength is less than a transmittance of the color filter of light of a second wavelength and the second wavelength is greater than the first wavelength, and an angle-dependent color change of the display panel in the emission area of the substrate at standard coordinates (0.1754, 0.1579) is within a trajectory range of about 10 of a MacAdams ellipse.

### CROSS-REFERENCE TO RELATED APPLICATION(S)

This application claims priority to and benefits of Korean Patent Application No. 10-2023-0104345 under 35 U.S.C. § 119, filed on Aug. 9, 2023, in the Korean Intellectual Property Office, the entire contents of which are incorporated herein by reference.

### BACKGROUND

### 1. Technical Field

One or more embodiments relate to a display apparatus including a light emitting device and a color filter.

### 2. Description of the Related Art

In general, light emitting devices such as organic light emitting diodes and thin film transistors are arranged over a substrate in a display apparatus and the display apparatus operates by causing the light emitting devices to emit light. Each pixel of the display apparatus may include a light emitting device such as an organic light emitting diode in which an intermediate layer including an emission layer is arranged between a pixel electrode and an opposite electrode. The display apparatus generally controls the light emission or light emission level of each pixel through a thin film transistor electrically connected to the pixel electrode. Some or a number of layers included in the light emitting device are commonly provided in light emitting devices.

Recently, display apparatuses have been used for various purposes. As display apparatuses have been used in various fields, requirements for the image characteristics of display apparatuses have also diversified.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

One or more embodiments include a display apparatus with improved image characteristics.

Additional aspects will be set forth in part in the description which follows and, in part, will be apparent from the description, or may be learned by practice of embodiments of the disclosure.

According to one or more embodiments, a display apparatus may include a light emitting device disposed over an emission area of a substrate and including a pixel electrode, an emission layer, and an opposite electrode; and a display panel including a color filter disposed over the light emitting device, wherein a transmittance of the color filter of light of a first wavelength is less than a transmittance of the color filter of light of a second wavelength and the transmittance of the color filter of light of the second wavelength is about 0.5 or less, the first wavelength is in a range of about 380 nm to about 460 nm, the second wavelength is in a range of about 460 nm to about 780 nm, a wavelength-dependent transmittance graph of the color filter has a negative slope of less than about 0 at a wavelength of about 460 nm, an emission spectrum of the display panel in the emission area of the substrate has a tristimulus value Z in a range of about 0.82 to about 1, and an angle-dependent color change of the display panel in the emission area of the substrate at standard coordinates (0.1754, 0.1579) is within a MacAdams ellipse range of about 10 or less.

According to an embodiment, a peak wavelength of the wavelength-dependent transmittance graph of the color filter may be about 460 nm or less.

According to an embodiment, the emission layer may include a material emitting light of the first wavelength.

According to an embodiment, the pixel electrode may include a lower transparent electrode, a metal electrode disposed on the lower transparent electrode, and an upper transparent electrode, and the opposite electrode may include a metal layer.

According to an embodiment, the emission layer may include a first emission layer and a second emission layer disposed over the first emission layer and vertically spaced apart from the first emission layer, wherein the light emitting device may further include a first charge generation layer disposed between the first emission layer and the second emission layer.

According to an embodiment, the emission layer may further include a third emission layer disposed between the second emission layer and the opposite electrode, and the light emitting device may further include a second charge generation layer disposed between the second emission layer and the third emission layer.

According to an embodiment, the light emitting device may further include a lower common layer disposed on a lower surface of the emission layer and including at least one of a hole transport layer and a hole injection layer, and an upper common layer disposed on an upper surface of the emission layer and including at least one of an electron transport layer and an electron injection layer.

According to an embodiment, the display apparatus may further include a first inorganic encapsulation layer disposed over the light emitting device, an organic encapsulation layer disposed over the first inorganic encapsulation layer, and a second inorganic encapsulation layer disposed over the organic encapsulation layer.

According to an embodiment, the display apparatus may further include a touch sensor layer disposed over the second inorganic encapsulation layer, wherein the color filter may be disposed over the touch sensor layer.

According to an embodiment, the display apparatus may further include a light blocking pattern disposed over the touch sensor layer and including an upper opening exposing an upper surface of the touch sensor layer, wherein the color filter may be disposed on the exposed upper surface of the touch sensor layer and in the upper opening of the light blocking pattern.

According to an embodiment, the display apparatus may further include a cover window disposed over the color filter, and a window adhesive layer disposed between the color filter and the cover window, the window adhesive layer including an optically clear adhesive.

According to an embodiment, the display apparatus may further include a pixel circuit layer disposed over the substrate, the pixel circuit layer including a thin film transistor, wherein the thin film transistor may include a semiconductor layer, a gate electrode, a source electrode, and a drain electrode, and the pixel electrode may be electrically connected to the thin film transistor.

According to an embodiment, the display apparatus may further include a buffer layer disposed between the substrate and the thin film transistor, a gate insulating layer disposed between the semiconductor layer and the gate electrode, and an interlayer insulating layer disposed over the gate electrode, wherein the source electrode and the drain electrode may be disposed on the interlayer insulating layer.

According to one or more embodiments, a display apparatus may include a light emitting device disposed over an emission area of a substrate and emitting light of a first wavelength; and a display panel including a color filter disposed over the light emitting device, wherein a transmittance of the color filter of light of the first wavelength may be less than a transmittance of the color filter of light of a second wavelength and the second wavelength may be greater than the first wavelength, and an angle-dependent color change of the display panel in the emission area of the substrate at standard coordinates (0.1754, 0.1579) may be within a trajectory range of about 10 of a MacAdams ellipse.

According to an embodiment, the first wavelength may include a visible light wavelength of about 460 nm or less, and the second wavelength may include a visible light wavelength of about 460 nm or more.

According to an embodiment, a wavelength-dependent transmittance graph of the color filter may have a negative slope at a wavelength of about 460 nm, and a peak wavelength of the wavelength-dependent transmittance graph of the color filter may be about 460 nm or less.

According to an embodiment, the light emitting device may include a transparent pixel electrode, an emission layer disposed over the transparent pixel electrode, and a transparent opposite electrode.

According to an embodiment, an emission spectrum of the display panel in the emission area of the substrate may have a tristimulus value Z in a range of about 0.8 to about 1.

According to an embodiment, an emission spectrum of the display panel in the emission area of the substrate may have a tristimulus value Z in a range of about 0.82 to about 1, and the light emitting device may include a pixel electrode including a lower transparent electrode, a metal electrode disposed over the lower transparent electrode, and an upper transparent electrode, an emission layer disposed over the pixel electrode, and an opposite electrode including a metal layer.

According to an embodiment, the display apparatus may further include a thin film encapsulation layer disposed over the light emitting device and encapsulating the light emitting device.

### BRIEF DESCRIPTION OF THE DRAWINGS

The above and other aspects, features, and advantages of embodiments will be more apparent from the following description taken in conjunction with the accompanying drawings, in which:

FIG. 1 is a schematic plan view schematically illustrating a portion of a display apparatus according to an embodiment;

FIG. 2 is a schematic diagram of an equivalent circuit of a pixel according to an embodiment;

FIG. 3 is a schematic diagram schematically illustrating a schematic cross-section of a display apparatus in a display area of a substrate, which corresponds to a schematic cross-section taken along line I-I′ of FIG. 1, according to an embodiment;

FIG. 4 is a schematic diagram schematically illustrating a schematic cross-section of a display apparatus in a display area of a substrate, according to an embodiment;

FIG. 5A is a schematic cross-sectional view illustrating a light emitting device according to an embodiment;

FIG. 5B is a schematic cross-sectional view illustrating a light emitting device according to an embodiment;

FIG. 6A is a graph illustrating the wavelength-dependent transmittance of a color filter according to an embodiment;

FIG. 6B is a graph illustrating the wavelength-dependent transmittance of a color filter according to an embodiment;

FIG. 7A is an emission spectrum illustrating the wavelength-dependent emission intensity of a display apparatus according to Comparative Example 1A;

FIG. 7B is an emission spectrum illustrating the wavelength-dependent emission intensity of a display apparatus according to Comparative Example 1B;

FIG. 7C is an emission spectrum illustrating the wavelength-dependent emission intensity of a display apparatus according to Experimental Example 1;

FIG. 8A illustrates color coordinate measurement results for a display apparatus according to Comparative Example 1A;

FIG. 8B illustrates color coordinate measurement results for a display apparatus according to Comparative Example 1B;

FIG. 8C illustrates the color coordinate measurement results for a display apparatus according to Experimental Example 1 of the disclosure;

FIG. 9A is a schematic diagram illustrating the color coordinates of a display apparatus according to Comparative Example 2A;

FIG. 9B is a schematic diagram illustrating the color coordinates of a display apparatus according to Comparative Example 2B;

FIG. 9C is a schematic diagram illustrating the color coordinates of a display apparatus according to Comparative Example 2C; and

FIG. 9D is a schematic diagram illustrating the color coordinates of a display apparatus according to Experimental Example 2 of the disclosure.

### DETAILED DESCRIPTION OF THE EMBODIMENTS

Reference will now be made in detail to embodiments, examples of which are illustrated in the accompanying drawings, wherein like reference numerals refer to like elements throughout. In this regard, the embodiments may have different forms and should not be construed as being limited to the descriptions set forth herein. Accordingly, the embodiments are described below, by referring to the figures, to explain aspects of the description.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

Throughout the disclosure, the expression “at least one of a, b or c” indicates only a, only b, only c, both a and b, both a and c, both b and c, all of a, b, and c, or variations thereof.

The disclosure may include various embodiments and modifications, and embodiments thereof are illustrated in the drawings and will be described herein in detail. The effects and features of the disclosure and the accomplishing methods thereof will become apparent from the embodiments described below in detail with reference to the accompanying drawings. However, the disclosure is not limited to the embodiments described below, and may be embodied in various modes.

Hereinafter, embodiments will be described in detail with reference to the accompanying drawings, and in the following description, like reference numerals will denote like elements and redundant descriptions thereof will be omitted for conciseness.

It will be understood that although terms such as “first” and “second” may be used herein to describe various elements, these elements should not be limited by these terms and these terms are only used to distinguish one element from another element. For example, a first element may be referred to as a second element, and similarly, a second element may be referred to as a first element without departing from the scope of the disclosure.

As used herein, the singular forms “a,” “an,” and “the” are intended to include the plural forms as well, unless the context clearly indicates otherwise.

It will be understood that terms such as “comprises,” “comprising,” “includes,” and/or “including,”, “has,” “have,” and/or “having,” and variations thereof when used in this specification, specify the presence of stated features, integers, steps, operations, elements, components, and/or groups thereof, but do not preclude the presence or addition of one or more other features, integers, steps, operations, elements, components, and/or groups thereof.

It will be understood that when a layer, region, area, component, or element is referred to as being “on” another layer, region, area, component, or element, it may be “directly on” the other layer, region, area, component, or element or may be “indirectly on” the other layer, region, area, component, or element with one or more intervening layers, regions, areas, components, or elements therebetween.

The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

When an element is described as ‘not overlapping’ or ‘to not overlap’ another element, this may include that the elements are spaced apart from each other, offset from each other, or set aside from each other or any other suitable term as would be appreciated and understood by those of ordinary skill in the art.

The terms “face” and “facing” mean that a first element may directly or indirectly oppose a second element. In a case in which a third element intervenes between the first and second element, the first and second element may be understood as being indirectly opposed to one another, although still facing each other.

Sizes of elements in the drawings may be exaggerated for convenience of description. In other words, because the sizes and shapes of components in the drawings are arbitrarily illustrated for convenience of description, the disclosure is not limited thereto.

When an embodiment may be implemented differently, a particular process order may be performed differently from the described order. For example, two processes described in succession may be performed substantially at the same time or may be performed in an order opposite to the described order.

It will be understood that when a layer, region, or component is referred to as being “connected to” another layer, region, or component, it may be “directly connected to” the other layer, region, or component or may be “indirectly connected to” the other layer, region, or component with one or more intervening layers, regions, or components therebetween. For example, it will be understood that when a layer, region, area, component, or element is referred to as being “electrically connected to” another layer, region, area, component, or element, it may be “directly electrically connected to” the other layer, region, area, component, or element or may be “indirectly electrically connected to” the other layer, region, area, component, or element with one or more intervening layers, regions, areas, components, or elements therebetween.

Throughout the disclosure, like reference numerals may refer to like elements. Hereinafter, display apparatuses according to embodiments will be described.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within +30%, 20%, 10%, 5% of the stated value.

Unless otherwise defined or implied herein, all terms (including technical and scientific terms) used herein have the same meaning as commonly understood by one of ordinary skill in the art to which the disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

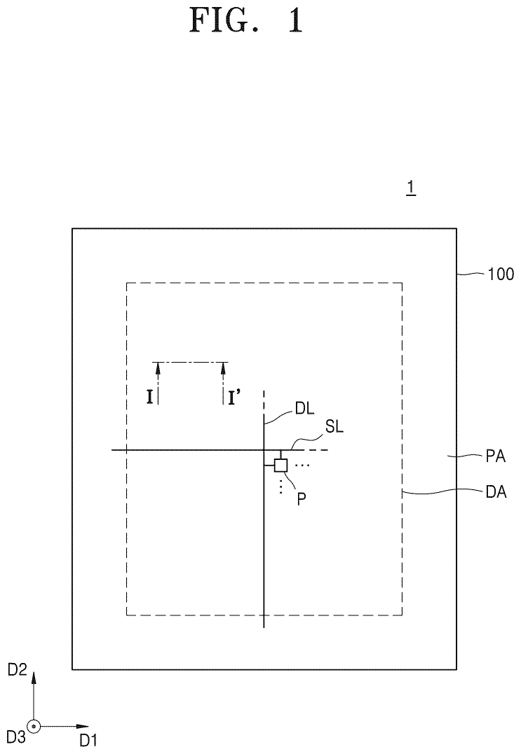

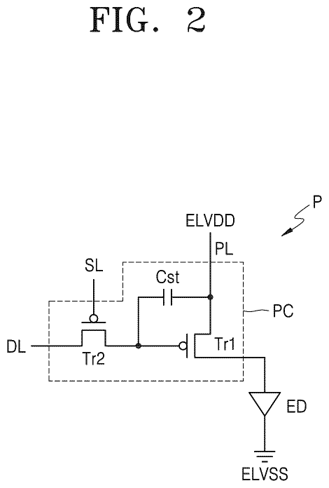

FIG. 1 is a schematic plan view schematically illustrating a portion of a display apparatus according to an embodiment. FIG. 2 is a schematic diagram of an equivalent circuit of a pixel according to an embodiment.

Referring to FIGS. 1 and 2, a substrate 100 of a display apparatus 1 according to an embodiment may include a display area DA and a peripheral area PA. The peripheral area PA may be arranged (or disposed) outside of the display area DA to surround or be adjacent to the display area DA. A driving circuit unit and various lines for transmitting electrical signals to be transmitted to the display area DA may be located (or disposed) in the peripheral area PA. The display apparatus 1 may provide an image by using light emitted from pixels P arranged in the display area DA. Each of the pixels P of the display area DA may emit red, green, blue, or white light.

Each of the pixels P may include a light emitting device ED. For example, the light emitting device ED may emit red, green, or blue light or may emit red, green, blue, or white light. The light emitting device ED may include an organic light emitting diode (OLED) or an inorganic light emitting diode. Each of the pixels P may be connected to a pixel circuit PC as illustrated in FIG. 2. The pixel circuit PC may include first and second thin film transistors Tr1 and Tr2 and a storage capacitor Cst. The pixel circuit PC may be connected to a scan line SL, a data line DL, and a driving voltage line PL. In an embodiment, the scan line SL may extend in a first direction D1 as illustrated in FIG. 1. The data line DL and the driving voltage line PL may extend in a second direction D2. The first direction D1 may be parallel to the upper surface of the substrate 100. The second direction D2 may intersect the first direction D1. A third direction D3 may intersect the first direction D1 and the second direction D2. For example, the first direction D1 may be an x-axis direction, the second direction D2 may be a y-axis direction, and the third direction D3 may be a z-axis direction; however, the disclosure is not limited thereto.

According to driving of the pixel circuit PC, each of the pixels P may emit light and the display area DA may provide an image through light emitted from pixels P. As described above, herein, the pixel P may be defined as an emission area emitting any one of red light, green light, blue light, and white light.

The peripheral area PA may be an area in which pixels P are not arranged, and may not provide an image. A printed circuit board including an internal driving circuit unit, a power supply line, and a driving circuit unit for driving the pixels Por a terminal unit to which a driver IC is connected may be arranged in the peripheral area PA.

As illustrated in FIG. 2, the light emitting device ED is connected to the pixel circuit PC in each of the pixels P. The pixel circuit PC may include a first thin film transistor Tr1, a second thin film transistor Tr2, and a storage capacitor Cst.

The second thin film transistor Tr2 may be a switching thin film transistor and may be connected to the scan line SL and the data line DL. The second thin film transistor Tr2 may transmit a data voltage input from the data line DL, to the first thin film transistor Tr1 according to a switching voltage input from the scan line SL.

The storage capacitor Cst may be connected to the second thin film transistor Tr2 and the driving voltage line PL. The storage capacitor Cst may store a voltage corresponding to the difference between a voltage received from the second thin film transistor Tr2 and a first power voltage ELVDD supplied to the driving voltage line PL.

The first thin film transistor Tr1 may be a driving thin film transistor and may be connected to the driving voltage line PL and the storage capacitor Cst. The first thin film transistor Tr1 may control a driving current flowing from the driving voltage line PL through the light emitting device ED in response to a voltage value stored in the storage capacitor Cst. The light emitting device ED may emit light with a brightness according to the driving current. An opposite electrode (for example, a cathode) of the light emitting device ED may be supplied with a second power voltage ELVSS.

FIG. 2 illustrates that the pixel circuit PC may include two thin film transistors Tr1 and Tr2 and one storage capacitor Cst; however, in other embodiments, the pixel circuit PC may include three or more transistors.

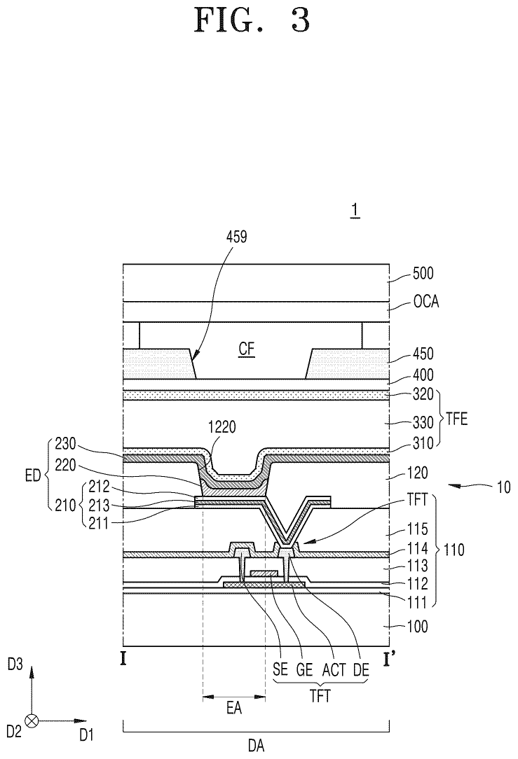

FIG. 3 is a schematic diagram schematically illustrating a schematic cross-section of a display apparatus in a display area of a substrate, which corresponds to a schematic cross-section taken along line I-I′ of FIG. 1, according to an embodiment.

Referring to FIG. 3, the display apparatus 1 may include a display panel 10. The display panel 10 may include a display area DA of the substrate 100, a pixel circuit layer 110 over the display area DA of the substrate 100, a light emitting device ED, an encapsulation layer TFE, a touch sensor layer 400, a color filter CF, a light blocking pattern 450, and a cover window 500.

The substrate 100 may include a glass material or a polymer resin. For example, the substrate 100 may include a glass material including silicon oxide (SiOₓ) as a main component or may include a polymer resin such as polyethersulfone, polyarylate, polyetherimide, polyethylene naphthalate, polyethylene terephthalate, polyphenylene sulfide, polyimide, polycarbonate, cellulose triacetate, and/or cellulose acetate propionate.

The pixel circuit layer 110 may be disposed over the substrate 100. The pixel circuit layer 110 may include a pixel circuit PC (see FIG. 2) and insulating layers. For example, the pixel circuit layer 110 may include a thin film transistor TFT, a storage capacitor Cst (see FIG. 2), a buffer layer 111, a gate insulating layer 112, an interlayer insulating layer 113, a protection layer 114, and a planarization insulating layer 115.

The thin film transistor TFT may include a semiconductor layer ACT, a gate electrode GE, a source electrode SE, and a drain electrode DE. The semiconductor layer ACT may include amorphous silicon, polysilicon, or an organic semiconductor material. The gate insulating layer 112 may be arranged between the semiconductor layer ACT and the gate electrode GE. The gate insulating layer 112 may secure the insulation between the semiconductor layer ACT and the gate electrode GE. The semiconductor layer ACT may include a channel area and impurity areas arranged on both sides of the channel area. One of the impurity areas arranged on both sides of the channel area may correspond to a source area and the other may correspond to a drain area. The gate insulating layer 112 may include an inorganic material such as silicon oxide (SiOₓ), silicon nitride (SiNₓ), and/or silicon oxynitride (SiO_{N}). The gate insulating layer 112 may be formed through chemical vapor deposition (CVD) or atomic layer deposition (ALD).

The interlayer insulating layer 113 may be disposed over the gate electrode GE. The interlayer insulating layer 113 may include an inorganic material such as silicon oxide (SiOₓ), silicon nitride (SiNₓ), and/or silicon oxynitride (SiO_{N}).

The source electrode SE and the drain electrode DE may be arranged in the interlayer insulating layer 113. In an embodiment, any one of the source electrode SE and the drain electrode DE may be omitted and replaced with a conductive semiconductor layer ACT.

The gate electrode GE, the source electrode SE, and the drain electrode DE may be formed of various conductive materials. The gate electrode GE may include at least one of molybdenum (Mo), aluminum (Al), copper (Cu), and titanium (Ti). For example, the gate electrode GE may include a single layer of molybdenum (Mo). Unlike this, the gate electrode GE may include a three-layer structure including a molybdenum layer, an aluminum layer, and a molybdenum layer. Each of the source electrode SE and the drain electrode DE may include at least one of copper (Cu), titanium (Ti), and aluminum (Al). Each of the source electrode SE and the drain electrode DE may include a single layer or multiple layers. For example, each of the source electrode SE and the drain electrode DE may include a three-layer structure including a titanium layer, an aluminum layer, and a titanium layer.

The protection layer 114 may be provided over the interlayer insulating layer 113 to cover the interlayer insulating layer 113, the source electrode SE, and the drain electrode DE. The protection layer 114 may prevent a metal line (not illustrated) from being exposed to an etching environment during the manufacturing process for the display apparatus 1.

The buffer layer 111 may be arranged between the thin film transistor TFT and the substrate 100. The buffer layer 111 may include an inorganic material such as silicon oxide (SiOₓ), silicon nitride (SiNₓ), and/or silicon oxynitride (SiO_{N}). The buffer layer 111 may increase the smoothness of the upper surface of the substrate 100 or may prevent the penetration of impurities into the semiconductor layer ACT of the thin film transistor TFT from the substrate 100.

The planarization insulating layer 115 may be disposed over the protection layer 114. The planarization insulating layer 115 may be formed of, for example, an organic material such as acryl, benzocyclobutene (BCB), or hexamethyldisiloxane (HMDSO). In FIG. 3, the planarization insulating layer 115 is illustrated as including a single layer; however, the planarization insulating layer 115 may include multiple layers.

The light emitting device ED may include a pixel electrode 210, an emission layer 220, and an opposite electrode 230. The pixel electrode 210 may be disposed over the planarization insulating layer 115. The pixel electrode 210 may be connected to any one of the source electrode SE or the drain electrode DE corresponding thereto by passing through the planarization insulating layer 115. Accordingly, the pixel electrode 210 may be electrically connected to the thin film transistor TFT. The pixel electrode 210 may be an anode.

The pixel electrode 210 may include a lower transparent electrode 211, a metal electrode 213, and an upper transparent electrode 212. The lower transparent electrode 211 may include a transparent conductive oxide. The transparent conductive oxide may include at least one of indium tin oxide (ITO), indium zinc oxide (IZO), zinc oxide (ZnO), indium oxide (In₂O₃), indium gallium oxide (IGO), and aluminum zinc oxide (AZO). The metal electrode 213 may be disposed over the lower transparent electrode 211. The metal electrode 213 may include Ag or an Ag alloy. As another example, the metal electrode 213 may include Mg, Al, Pt, Pd, Au, Ni, Nd, Ir, Cr, or any compound thereof. The upper transparent electrode 212 may be arranged on the upper surface of the metal electrode 213. The upper transparent electrode 212 may include a transparent conductive oxide, and the transparent conductive oxide may include any one of the materials described above in the example of the lower transparent electrode 211. As an example, the pixel electrode 210 may include a stack of ITO/Ag/ITO.

The light emitting device ED may be arranged in each pixel P (see FIG. 1). The light emitting device ED may emit light of a first wavelength. Light of the first wavelength may be blue light. For example, the first wavelength may be in a range of about 380 nm to about 460 nm. The light emitting device ED may further emit a portion of light of a second wavelength. The second wavelength may be in a range of about 460 nm to about 780 nm. Light of the second wavelength may be green light or red light.

The display apparatus 1 may further include a pixel definition layer 120. The pixel definition layer 120 may be disposed over the pixel electrode 210. The pixel definition layer 120 may include an emission opening 1220. The emission opening 1220 may expose the upper surface of the pixel electrode 210 by passing through the pixel definition layer 120. The upper surface of the pixel electrode 210 may correspond to the upper surface of the upper transparent electrode 212. The emission opening 1220 may define an emission area EA of the pixel P (see FIG. 1). As described above, light of the first wavelength may be emitted from the light emitting device ED of the emission area EA. The emission area EA may be a blue emission area, and the light emitting device ED may be a blue light emitting device.

The pixel definition layer 120 may cover the edge of the pixel electrode 210 to increase the distance between the edge of the pixel electrode 210 and the opposite electrode 230 to prevent an arc from occurring at the edge of the pixel electrode 210.

The pixel definition layer 120 may include an organic insulating material such as polyimide, polyamide, acrylic resin, benzocyclobutene, HMDSO, or phenolic resin. For example, the pixel definition layer 120 may include an inorganic insulating material. For example, the pixel definition layer 120 may have a multilayer structure including an inorganic insulating material and an organic insulating material. The pixel definition layer 120 may be formed by a method such as spin coating.

In an embodiment, the pixel definition layer 120 may include a black matrix. For example, the pixel definition layer 120 may include a light blocking material and may be provided in black. The light blocking material may include, for example, a resin or paste including carbon black, carbon nanotube, and/or black dye, metal particles (for example, nickel, aluminum, molybdenum, or any alloy thereof), metal oxide particles (for example, chromium oxide), or metal nitride particles (for example, chromium nitride).

The emission layer 220 may be disposed over the pixel electrode 210. The emission layer 220 may be laterally spaced from each other. The emission layer 220 may emit light of the first wavelength. The fact that the light emitting device ED emits light may mean that light is emitted from the emission layer 220. The emission layer 220 may include an organic light emitting material; however, the disclosure is not limited thereto. As an example, the emission layer 220 may include a fluorescent or phosphorescent material. The light emitted from the emission layer 220 may have a peak wavelength of less than about 460 nm. For example, the light emitted from the emission layer 220 may have a peak wavelength in the first wavelength range.

The opposite electrode 230 may be disposed over the emission layer 220. The opposite electrode 230 may further extend onto the inner wall of the emission opening 1220 and the upper surface of the pixel definition layer 120. The opposite electrode 230 may be a common electrode. For example, the opposite electrode 230 may be a common layer integrally formed to entirely cover the substrate 100, for example, to entirely cover the display area DA (see FIG. 1) of the substrate 100.

The opposite electrode 230 may be a cathode that is an electron injection electrode. A metal, an alloy, an electrically conductive compound, or any combination thereof having a low work function may be used as the material of the opposite electrode 230. The opposite electrode 230 may include a reflective electrode. The opposite electrode 230 may include, for example, lithium (Li), silver (Ag), magnesium (Mg), aluminum (Al), aluminum-lithium (Al—Li), calcium (Ca), magnesium-indium (Mg—In), magnesium-silver (Mg—Ag), ytterbium (Yb), silver-ytterbium (Ag—Yb), ITO, IZO, or any combination thereof. The opposite electrode 230 may have a single-layer structure including a single layer or a multilayer structure including layers.

The light emitting device ED may further include at least one of a lower common layer (not illustrated) and an upper common layer (not illustrated). The lower common layer may be arranged on the lower surface of the emission layer 220. For example, the lower common layer may include at least one of a hole transport layer (HTL) and a hole injection layer (HIL). The upper common layer may be arranged on the upper surface of the emission layer 220. The upper common layer may include at least one of an electron transport layer (ETL) and an electron injection layer (EIL). Each of the lower common layer and the upper common layer may be a common layer integrally formed to entirely cover the entire substrate 100, for example, to entirely cover the display area DA (see FIG. 1) of the substrate 100, like the opposite electrode 230 described below.

The encapsulation layer TFE may be disposed over the light emitting device ED and the pixel definition layer 120 to encapsulate the light emitting device ED. The encapsulation layer TFE may include a first inorganic encapsulation layer 310, a second inorganic encapsulation layer 320, and an organic encapsulation layer 330. The first inorganic encapsulation layer 310 may be provided over the light emitting device ED to cover the light emitting device ED. The first inorganic encapsulation layer 310 may include an inorganic insulating material. The inorganic insulating material may include aluminum oxide, titanium oxide, tantalum oxide, hafnium oxide, zinc oxide, silicon oxide, silicon nitride, and/or silicon oxynitride. The first inorganic encapsulation layer 310 may be formed by a CVD process. The first inorganic encapsulation layer 310 may be transparent.

The organic encapsulation layer 330 may be arranged on the upper surface of the first inorganic encapsulation layer 310 to cover the upper surface of the first inorganic encapsulation layer 310. The organic encapsulation layer 330 may include a polymer. The polymer may include acryl-based resin, epoxy-based resin, polyimide, polyethylene, and/or the like within the spirit and the scope of the disclosure. For example, the organic encapsulation layer 330 may include acryl-based resin such as polymethylmethacrylate or polyacrylic acid. The organic encapsulation layer 330 may be formed by curing a monomer or applying a polymer. The organic encapsulation layer 330 may cover the unevenness of the light emitting device ED, and accordingly, the upper surface of the organic encapsulation layer 330 may be flatter than the upper surface of the first inorganic encapsulation layer 310. The organic encapsulation layer 330 may be transparent.

The second inorganic encapsulation layer 320 may be provided on the upper surface of the organic encapsulation layer 330. The second inorganic encapsulation layer 320 may include the inorganic insulating material described above in the example of the first inorganic encapsulation layer 310. The second inorganic encapsulation layer 320 may be formed by a CVD process. The second inorganic encapsulation layer 320 may be transparent.

The display apparatus 1 may further include a touch sensor layer 400. The touch sensor layer 400 may be disposed over the encapsulation layer TFE. The touch sensor layer 400 may sense a user's touch input. The touch sensor layer 400 may sense a user's touch input by a resistive method or a capacitive method. The touch sensor layer 400 may include stacked insulating layers and conductive layers. The conductive layers may be arranged between the insulating layers and may function as touch electrodes. Unlike the illustration, the touch sensor layer 400 may be omitted.

The light blocking pattern 450 may be disposed over the touch sensor layer 400. The light blocking pattern 450 may absorb or reflect light. The light blocking pattern 450 may include an upper opening 459. The upper opening 459 may expose the upper surface of the touch sensor layer 400 by passing through the light blocking pattern 450. The upper opening 459 may vertically overlap the emission opening 1220. The light blocking pattern 450 may include an upper opening 459 and may have a substantially mesh shape in the plan view. The light blocking pattern 450 may include an insulating material (for example, an organic insulating material) and a light blocking material. The light blocking material may include black pigment or black dye. The light blocking pattern 450 may include, for example, a black matrix. The light blocking pattern 450 may be arranged corresponding to a non-emission area and may prevent color mixing due to light leakage between the pixels P (see FIG. 1). The non-emission area may be an area that does not vertically overlap the emission opening 1220. The light blocking pattern 450 may vertically overlap the pixel definition layer 120. As described above, in case that the pixel definition layer 120 may include a light blocking material, the light blocking function of the pixel definition layer 120 and the light blocking pattern 450 may be maximized.

The color filter CF may be arranged on the upper surface of the touch sensor layer 400 and in the upper opening 459 of the light blocking pattern 450. The color filter CF may transmit only light of a given wavelength and may filter off light of other wavelengths.

The color filter CF may be disposed over the light emitting device ED. For example, the color filter CF may vertically overlap the emission opening 1220. The color filter CF may be a color filter transmitting light of the first wavelength. Accordingly, the light emitting device ED may emit light of the first wavelength, and the color filter CF may transmit the light of the first wavelength emitted from the light emitting device ED. For example, the color filter may be a blue color filter.

According to embodiments, the color filter CF may include a material having different transmittances depending on wavelengths. The color filter CF may have a structure having different absorptances depending on wavelengths. The color filter CF may have a high transmittance to light of the first wavelength and a low transmittance to light of the second wavelength. The first wavelength may be about 460 nm or less. For example, the first wavelength may be a visible light wavelength of about 460 nm or less. By way of example, the first wavelength may be in a range of about 380 nm to about 460 nm. The second wavelength may be greater than the first wavelength. The second wavelength may be more than about 460 nm. By way of example, the second wavelength may be in a range of about 460 nm to about 780 nm. The transmittance of the color filter to light of the first wavelength may be greater than the transmittance of the color filter to light of the second wavelength. The transmittance of the color filter to light of the second wavelength may be 0.5 or less.

The cover window 500 may be disposed over the color filter CF. The cover window 500 may be transparent. The cover window 500 may include at least one of glass, sapphire, and plastic. The cover window 500 may include, for example, ultra-thin glass (UTG) or colorless polyimide (CPI).

The display apparatus 1 may further include a window adhesive layer OCA. The window adhesive layer OCA may be arranged between the color filter CF and the cover window 500. The cover window 500 may be attached to the color filter CF through the window adhesive layer OCA. The window adhesive layer OCA may include an optically clear adhesive. The optically clear adhesive may include an organic material such as a polymer.

According to embodiments, the light emitting device ED may be a front light emitting device. The emission spectrum of the display panel 10 in the emission area EA may have a Z of about 0.82 to about 1. According to embodiments, by adjusting the wavelength-dependent transmittance of the color filter CF or the light emitting material of the emission layer 220, the Z of the emission spectrum of the display panel 10 may satisfy the above condition range. CIE XYZ may be a universal color space representing the color spectrum that the humans may sec. CIE tristimulus values may include X, Y, and Z, wherein X may be assigned to a red curve, Y may be assigned to a green curve, and Z may be assigned to a blue curve. As the Z of the emission spectrum is closer to 1, there may be more pure blue. According to embodiments, the display apparatus 1 may emit a large amount of pure blue wavelength light in the blue emission area and thus may have improved image characteristics.

An angle-dependent color change of the display panel 10 in the emission area EA at standard coordinates (0.1754, 0.1579) may be located within a McAdams ellipse range of about 10. The standard coordinates (0.1754, 0.1579) may correspond to the standard coordinates of blue. The McAdams ellipse may be an area of a chromaticity diagram that may include all colors that are indistinguishable to the average human eye from the color at the center of the ellipse. The McAdams ellipse range of about 10 or less may mean that it is difficult for the humans to recognize the color difference between two given colors. According to embodiments, because the angle-dependent color change at the standard coordinates (0.1754, 0.1579) is located within a MacAdams ellipse range of about 10 or less, it may be difficult for the user to recognize a color difference with respect to blue light emitted from the display panel 10 in the emission area EA. The user may equally recognize the colors seen from the front and side surfaces of the display apparatus 1. Accordingly, the image characteristics of the display apparatus 1 may be improved.

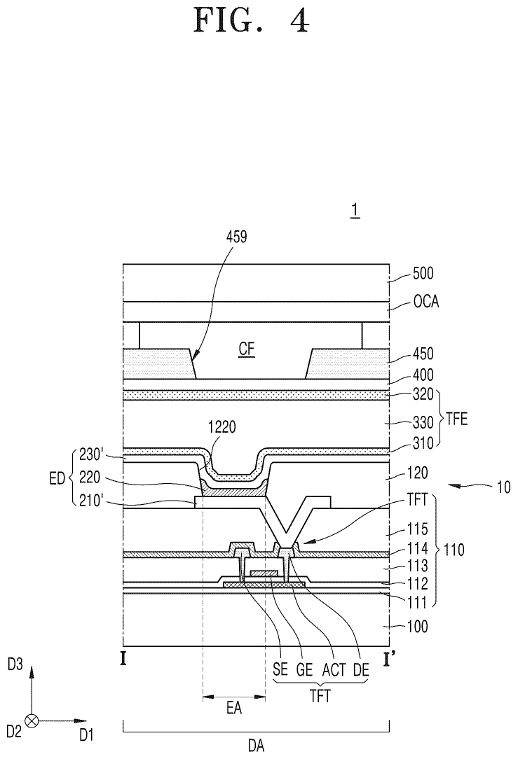

FIG. 4 is a schematic diagram schematically illustrating a schematic cross-section of a display apparatus in a display area of a substrate, which corresponds to a schematic cross-section taken along line I-I′ of FIG. 1, according to an embodiment. Hereinafter, redundant descriptions with those given above will be omitted for conciseness.

Referring to FIG. 4, the display apparatus 1 may include a display panel 10, and the display panel 10 may include a substrate 100, a pixel circuit layer 110, a light emitting device ED, an encapsulation layer TFE, a touch sensor layer 400, a color filter CF, a light blocking pattern 450, and a cover window 500.

The light emitting device ED may include a pixel electrode 210′, an emission layer 220, and an opposite electrode 230′. The pixel electrode 210′, the emission layer 220, and the opposite electrode 230′ may be substantially the same as those described above in the examples of FIG. 3. However, the pixel electrode 210′ may be a transparent pixel electrode. The pixel electrode 210′ may include a transparent conductive oxide. The transparent conductive oxide may include the materials described above in the examples of the lower transparent electrode 211 of FIG. 3. The pixel electrode 210′ may include a single transparent conductive oxide layer or multiple transparent conductive oxide layers. The pixel electrode 210′ may not include a metal layer, a metal electrode, or a reflective electrode. As an example, the emission layer 220 may be directly disposed over the pixel electrode 210′ and may contact the pixel electrode 210′.

The opposite electrode 230′ may be a transparent opposite electrode. The opposite electrode 230′ may include a transparent conductive oxide. The transparent conductive oxide may include the materials described above in the examples of the lower transparent electrode 211 of FIG. 3. The opposite electrode 230′ may include a single transparent conductive oxide layer or multiple transparent conductive oxide layers. The opposite electrode 230′ may not include a metal layer, a metal electrode, or a reflective electrode. As an example, the opposite electrode 230′ may be directly disposed over the emission layer 220 and may contact the emission layer 220.

According to embodiments, the display apparatus 1 may include a back light emitting device. The emission spectrum of the display panel 10 in the emission area EA may have a Z of about 0.8 to about 1. According to embodiments, the display apparatus 1 may emit a large amount of pure blue wavelength light in the blue emission area and thus may have improved image characteristics.

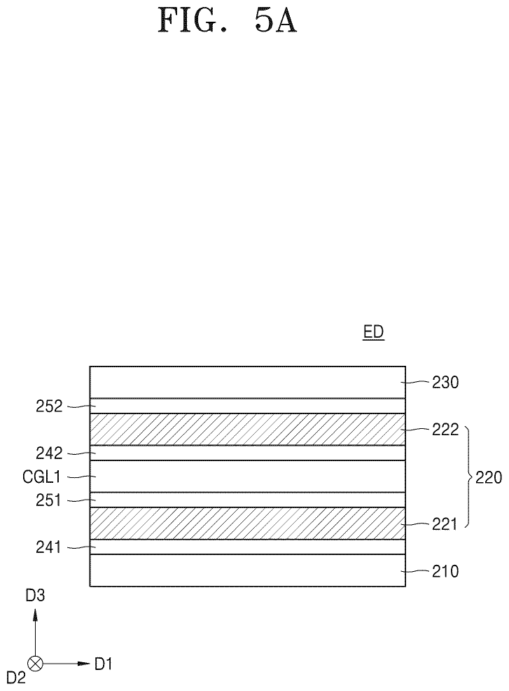

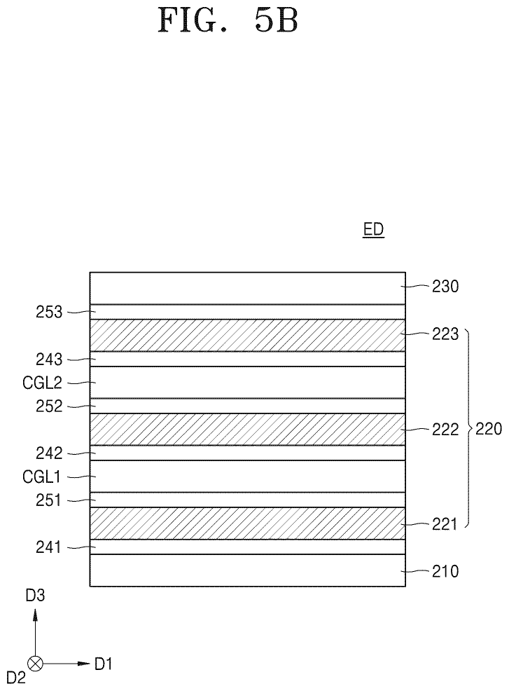

As described in FIGS. 3 and 4, the light emitting device ED may include one emission layer 220. However, the disclosure is not limited thereto. As illustrated in FIGS. 5A and 5B, the emission layer 220 of the light emitting device ED may have a tandem structure in which layers are stacked each other.

FIG. 5A is a schematic cross-sectional view illustrating a light emitting device according to an embodiment. Hereinafter, redundant descriptions with those given above will be omitted for conciseness.

Referring to FIG. 5A, the light emitting device ED may be an organic light emitting diode. The light emitting device ED may include a pixel electrode 210, an emission layer 220, a first charge generation layer CGL1, and an opposite electrode 230. The emission layer 220 may include a first emission layer 221 and a second emission layer 222. The first emission layer 221 may emit light of the first wavelength. The first emission layer 221 may be a blue emission layer.

The second emission layer 222 may be disposed over the first emission layer 221 and may be vertically spaced apart from the first emission layer 221. The second emission layer 222 may emit light of the first wavelength. The second emission layer 222 may be a blue emission layer. Unlike this, the second emission layer 222 may emit light of the second wavelength. The second emission layer 222 may be a yellow emission layer, a red emission layer, or a green emission layer.

The first charge generation layer CGL1 may be arranged between the first emission layer 221 and the second emission layer 222. The first charge generation layer CGL1 may adjust the charge between the first emission layer 221 and the second emission layer 222 to achieve a charge balance. The first charge generation layer CGL1 may include an n-type layer and a p-type layer that are stacked each other. The n-type layer may be provided adjacent to the first emission layer 221 and may supply electrons to the first emission layer 221. The p-type layer may be provided adjacent to the second emission layer 222 and may supply holes to the second emission layer 222.

The opposite electrode 230 may be arranged on the upper surface of the second emission layer 222.

The light emitting device ED may further include at least one of a first lower common layer 241 and a first upper common layer 251. The first lower common layer 241 may be arranged between the pixel electrode 210 and the first emission layer 221 and may include a first hole injection layer and/or a first hole transport layer. The first upper common layer 251 may be arranged between the first emission layer 221 and the first charge generation layer CGL1 and may include a first electron injection layer and/or a first electron transport layer.

The light emitting device ED may further include at least one of a second lower common layer 242 and a second upper common layer 252. The second lower common layer 242 may be arranged between the first charge generation layer CGL1 and the second emission layer 222 and may include a second hole injection layer and/or a second hole transport layer. The second upper common layer 252 may be arranged between the second emission layer 222 and the opposite electrode 230 and may include a second electron injection layer and/or a second electron transport layer.

FIG. 5B is a schematic cross-sectional view illustrating a light emitting device according to an embodiment. Hereinafter, redundant descriptions with those given above will be omitted for conciseness.

Referring to FIG. 5B, the light emitting device ED may be an organic light emitting diode. The light emitting device ED may include a pixel electrode 210, an emission layer 220, a first charge generation layer CGL1, a second charge generation layer CGL2, and an opposite electrode 230. The emission layer 220 may include a first emission layer 221, a second emission layer 222, and a third emission layer 223. The first emission layer 221 may emit light of the first wavelength. The first emission layer 221 may be a blue emission layer.

The second emission layer 222 may be arranged between the first emission layer 221 and the opposite electrode 230 and may be vertically spaced apart from the first emission layer 221. The second emission layer 222 may emit light of the first wavelength. The second emission layer 222 may be a blue emission layer. Unlike this, the second emission layer 222 may emit light of the second wavelength. The second emission layer 222 may be a yellow emission layer. Unlike this, the second emission layer 222 may be a red emission layer or a green emission layer. As another example, the second emission layer 222 may include a red emission layer, a yellow emission layer, and a green emission layer that are stacked each other.

The third emission layer 223 may be arranged between the second emission layer 222 and the opposite electrode 230. The third emission layer 223 may emit light of the first wavelength. The third emission layer 223 may be a blue emission layer.

The first charge generation layer CGL1 may be arranged between the first emission layer 221 and the second emission layer 222. The first charge generation layer CGL1 may be substantially the same as that described above with reference to FIG. 5A.

The second charge generation layer CGL2 may be arranged between the second emission layer 222 and the third emission layer 223. The second charge generation layer CGL2 may adjust the charge between the second emission layer 222 and the third emission layer 223 to achieve a charge balance. The second charge generation layer CGL2 may include an n-type layer and a p-type layer that are stacked each other. The n-type layer may be provided adjacent to the second emission layer 222 and may supply electrons to the second emission layer 222. The p-type layer may be provided adjacent to the third emission layer 223 and may supply holes to the third emission layer 223.

The light emitting device ED may further include at least one of a first lower common layer 241, a first upper common layer 251, a second lower common layer 242, and a second upper common layer 252. The second upper common layer 252 may be arranged between the second emission layer 222 and the second charge generation layer CGL2.

The light emitting device ED may further include at least one of a third lower common layer 243 and a third upper common layer 253. The third lower common layer 243 may be arranged between the second charge generation layer CGL2 and the third emission layer 223 and may include a third hole injection layer and/or a third hole transport layer. The third upper common layer 253 may be arranged between the second emission layer 222 and the opposite electrode 230 and may include a third electron injection layer and/or a third electron transport layer.

According to embodiments, the light emitting device ED may have a tandem structure as illustrated in FIG. 5A or 5B and thus may have high brightness and long life.

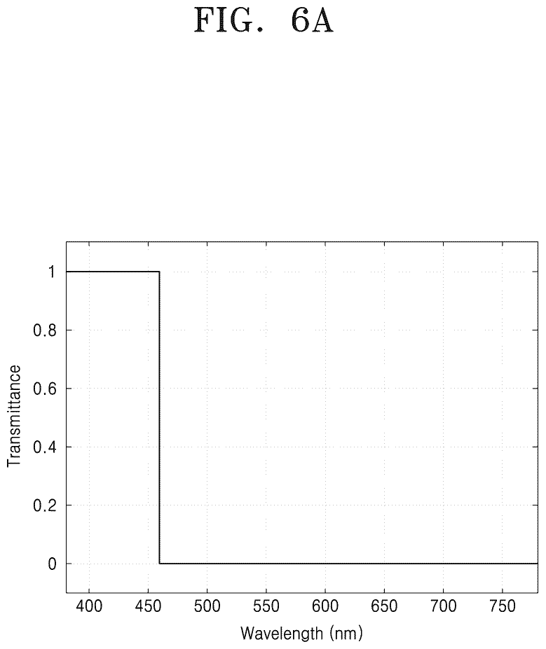

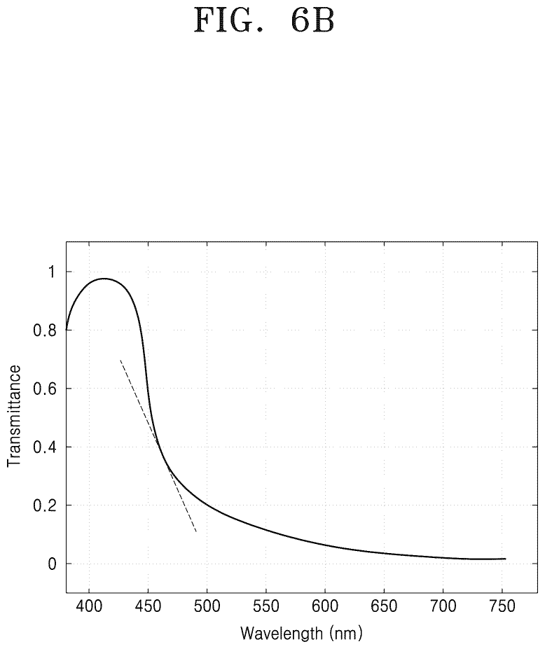

FIG. 6A is a graph illustrating the wavelength-dependent transmittance of a color filter according to an embodiment. FIG. 6B is a graph illustrating the wavelength-dependent transmittance of a color filter according to an embodiment.

Referring to FIGS. 6A and 6B, the color filter may have a transmittance of about 0.5 or less at a second wavelength of more than about 460 nm. The transmittance of the color filter to light of the first wavelength may be greater than the transmittance of the color filter to light of the second wavelength. The first wavelength may be in a range of about 380 nm or to about 460 nm.

Referring to FIG. 6B, the wavelength-dependent transmittance graph of the color filter may have a negative slope of less than about 0 at a wavelength of about 460 nm. The slope may be represented by a dotted line in FIG. 6B. The peak wavelength of the wavelength-dependent transmittance graph may correspond to the first wavelength. For example, the peak wavelength of the wavelength-dependent transmittance graph may be less than about 460 nm.

### [Measurement of Emission Spectrums and Color Coordinates Depending on Light Emitting Materials]

### Comparative Example 1A

A display apparatus including an emission layer including a light emitting material according to the related art is prepared. The emission spectrum and color coordinates of the display apparatus are measured.

### Comparative Example 1B

A display apparatus including an emission layer including a light emitting material according to the related art is prepared. The color coordinates of the display apparatus are measured. The light emitting material of Comparative Example 1B is different from the light emitting material of Comparative Example 1A. The emission spectrum and color coordinates of the display apparatus according to Comparative Example 1B are measured in the same way as in Comparative Example 1A.

### Experimental Example 1

A display apparatus including an emission layer including a light emitting material according to Experimental Example 1 is prepared. The emission spectrum and color coordinates of the display apparatus according to Experimental Example 1 are measured in the same way as in Comparative Example 1A.

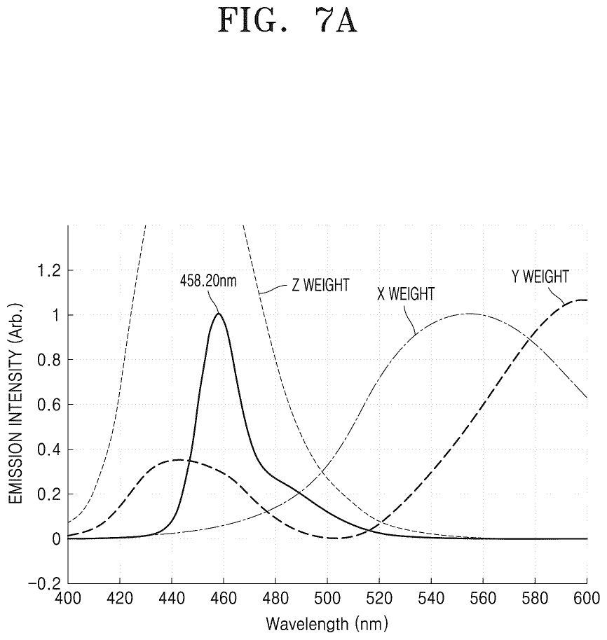

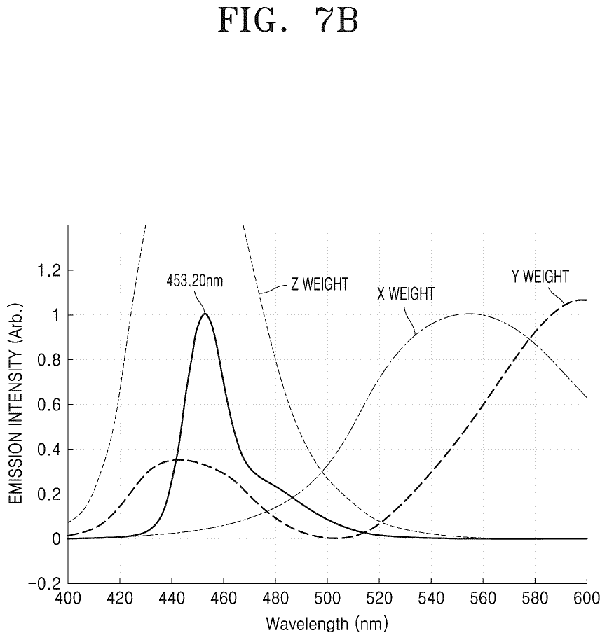

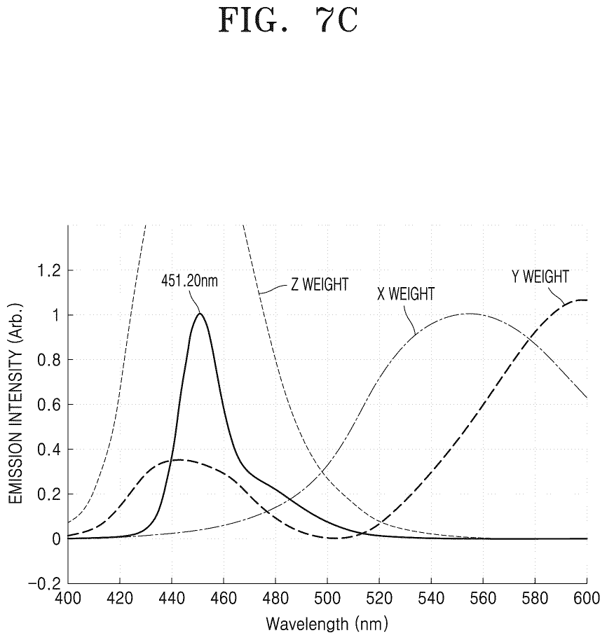

FIG. 7A is an emission spectrum illustrating the wavelength-dependent emission intensity of a display apparatus according to Comparative Example 1A. FIG. 7B is an emission spectrum illustrating the wavelength-dependent emission intensity of a display apparatus according to Comparative Example 1B. FIG. 7C is an emission spectrum illustrating the wavelength-dependent emission intensity of a display apparatus according to Experimental Example 1.

Referring to FIGS. 7A, 7B, and 7C, the emission spectrum of the display apparatus of Experimental Example 1 may be shifted to the left compared to the emission spectrum of the display apparatus of Comparative Example 1A of FIG. 7A and the emission spectrum of the display apparatus of Comparative Example 1B of FIG. 7B. For example, the wavelength range of the peak wavelength of the emission spectrum of the display apparatus of Experimental Example 1 may be less than the wavelength range of the peak wavelength of the emission spectrum of the display apparatus of Comparative Example 1A. The wavelength range of the peak wavelength of the emission spectrum of the display apparatus of Experimental Example 1 may be less than the wavelength range of the peak wavelength of the emission spectrum of the display apparatus of Comparative Example 1B.

Table 1 shows the results of analyzing tristimulus values from the emission spectrums of the display apparatus of Comparative Example 1A, the display apparatus of Comparative Example 1B, and the display apparatus of the experimental example. The display apparatus of Comparative Example 1A, the display apparatus of Comparative Example 1B, and the display apparatus of the experimental example used in the analysis of Table 1 may be back light emitting devices.

TABLE 1

| Tristimulus values of | Comparative | Comparative | Experimental |
|---|---|---|---|
| emission spectrum | Example 1 | Example 2 | Example |
| X | 13.5% | 14.2% | 14.4% |
| Y | 6.5% | 5.0% | 4.5% |
| Z | 80.0% | 80.8% | 81.8% |

Referring to Table 1 together with FIGS. 7A, 7B, and 7C, in the case of Experimental Example 1, the emission spectrum of the display panel 10 in the emission area EA may have a Z of 0.8 or more.

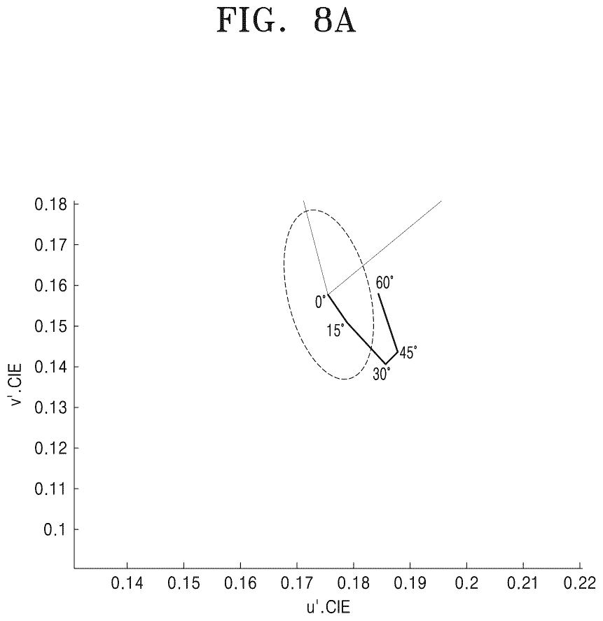

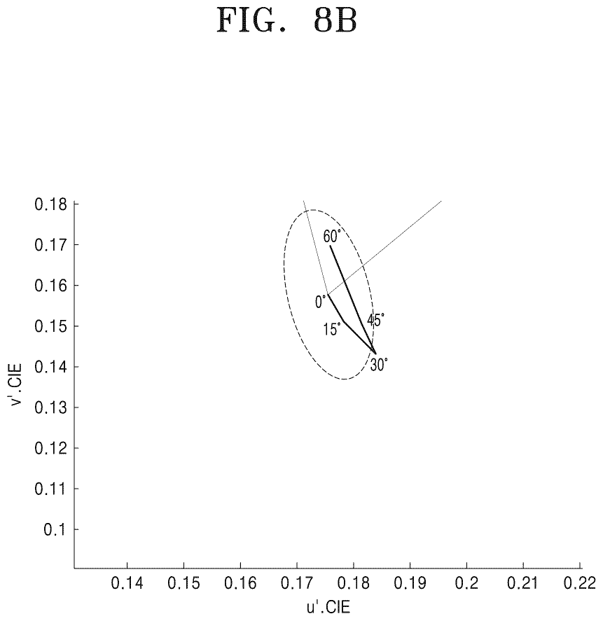

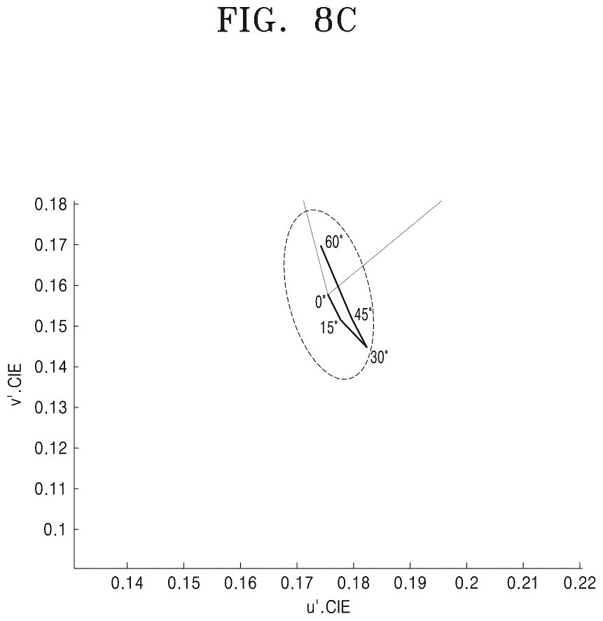

FIG. 8A illustrates the color coordinate measurement results of a display apparatus according to Comparative Example 1A. FIG. 8B illustrates the color coordinate measurement results of a display apparatus according to Comparative Example 1B. FIG. 8C illustrates the color coordinate measurement results of a display apparatus according to Experimental Example 1 of the disclosure. In FIGS. 8A, 8B, and 8C, a dotted line may represent a required trajectory. The required trajectory may be located within an ellipse that is McAdams ellipse 10. In FIGS. 8A, 8B, and 8C, 0°, 15°, 30°, 45°, and 60° may refer to viewing angles.

Referring to FIG. 8A, the angle-dependent color change of the display panel of the display apparatus of Comparative Example 1A at the standard coordinates (0.1754, 0.1579) may deviate from the required trajectory. For example, the angle-dependent color change of the display panel of the display apparatus of Comparative Example 1A at the standard coordinates (0.1754, 0.1579) may deviate from the range of McAdams ellipse 10.

Referring to FIG. 8B, the angle-dependent color change of the display panel of the display apparatus of Comparative Example 1B at the standard coordinates (0.1754, 0.1579) may deviate from the required trajectory. For example, the angle-dependent color change of the display panel of the display apparatus of Comparative Example 1B at the standard coordinates (0.1754, 0.1579) may deviate from the range of McAdams ellipse 10.

Referring to FIG. 8C, the angle-dependent color change of the display panel of the display apparatus of Experimental Example 1 at the standard coordinates (0.1754, 0.1579) may be located within the required trajectory range. The angle-dependent color change of the display panel of Experimental Example 1 at the standard coordinates (0.1754, 0.1579) may be located within the range of McAdams ellipse about 10 or less. Thus, in the case of the display apparatus of Experimental Example 1, a color change due to a viewing angle change with respect to blue light may not be observed by the human eyes.

### [Whether Required Trajectories are Satisfied Depending on Color Filters]

### Comparative Example 2A

A display apparatus not including a color filter is prepared. The color coordinates of the display apparatus are measured.

### Comparative Example 2B

A display apparatus including a color filter is prepared. The color filter of the display apparatus according to Comparative Example 2B filters off light of a wavelength of more than about 480 nm and transmits light of a wavelength of about 480 nm or less. The color coordinates of the display apparatus according to Comparative Example 2B are measured in the same way as in Comparative Example 2A.

### Comparative Example 2C

A display apparatus including a color filter is prepared. The color filter of the display apparatus according to Comparative Example 2C filters off light of a wavelength of more than about 470 nm and transmits light of a wavelength of about 470 nm or less. The color coordinates of the display apparatus according to Comparative Example 2C are measured in the same way as in Comparative Example 2A.

### Experimental Example 2

A display apparatus including a color filter is prepared. The color filter of the display apparatus according to the experimental example filters off light of a wavelength of more than about 460 nm and transmits light of a wavelength of about 460 nm or less. The transmittance characteristics of the color filter according to the same wavelength are the same as those in FIG. 6A or FIG. 6B. The color coordinates of the display apparatus according to the experimental example are measured in the same way as in Comparative Example 2A.

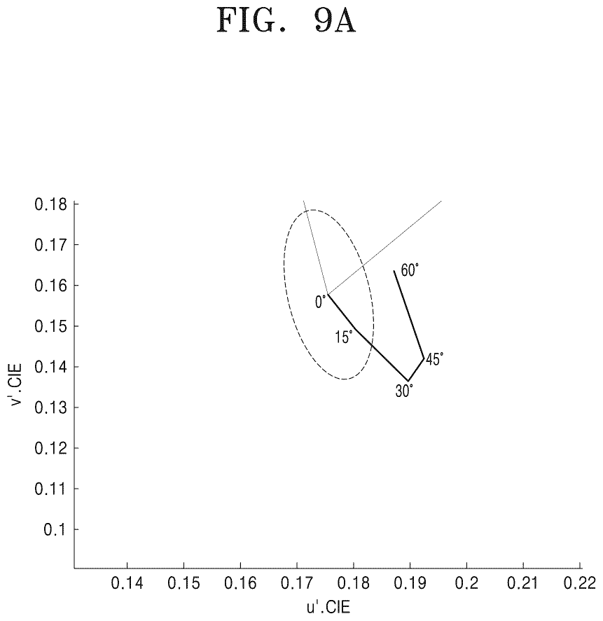

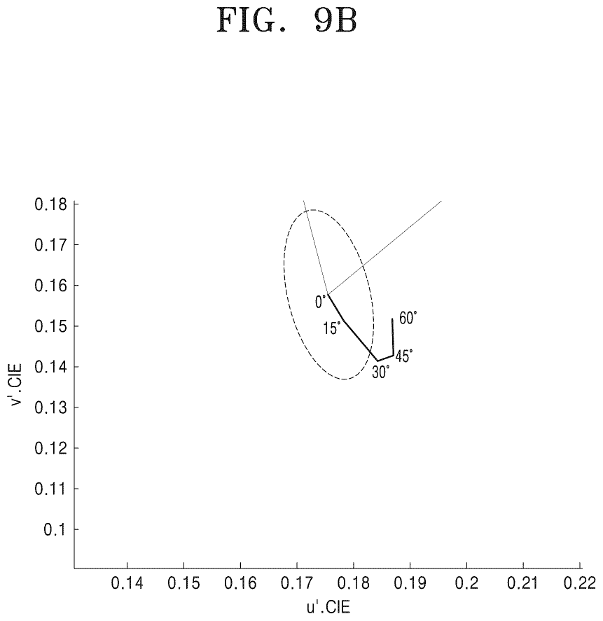

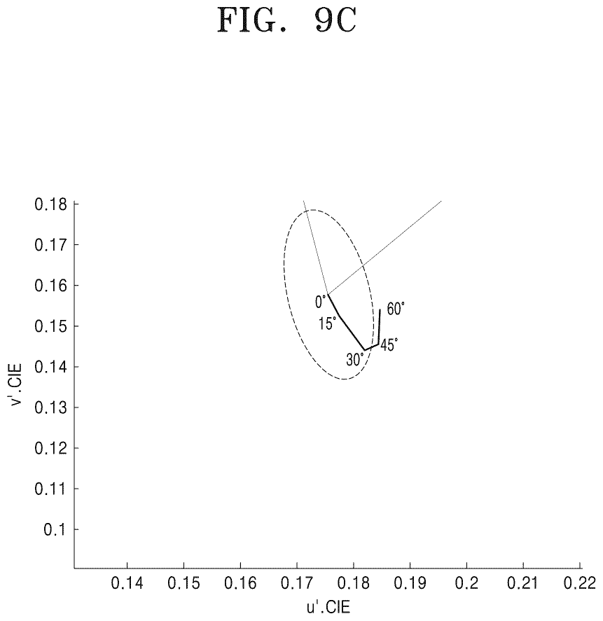

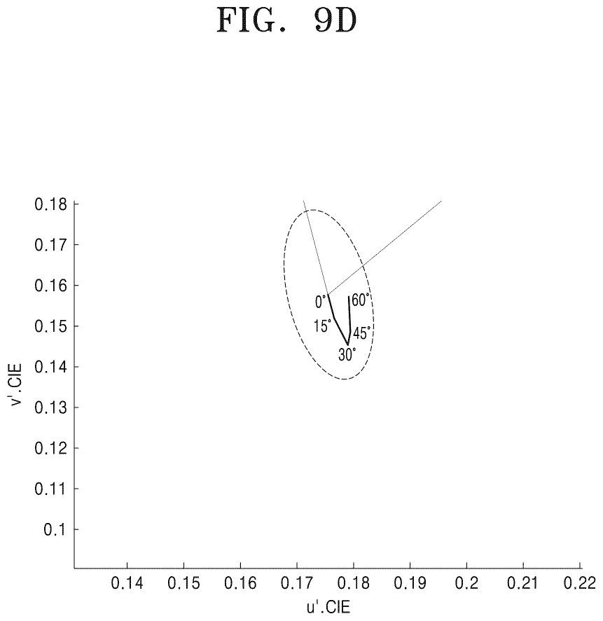

FIG. 9A is a schematic diagram illustrating the color coordinates of a display apparatus according to Comparative Example 2A. FIG. 9B is a schematic diagram illustrating the color coordinates of a display apparatus according to Comparative Example 2B. FIG. 9C is a schematic diagram illustrating the color coordinates of a display apparatus according to Comparative Example 2C. FIG. 9D is a schematic diagram illustrating the color coordinates of a display apparatus according to Experimental Example 2 of the disclosure. In FIGS. 9A, 9B, 9C, and 9D, a dotted line may represent a required trajectory. The required trajectory may be located within an ellipse that is McAdams ellipse 10. In FIGS. 9A, 9B, 9C, and 9D, 0°, 15°, 30°, 45°, and 60° may refer to viewing angles.

Referring to FIGS. 9A, 9B, and 9C, the angle-dependent color change of the display panel of the display apparatus of Comparative Example 2A at the standard coordinates (0.1754, 0.1579) may deviate from the required trajectory. The angle-dependent color change of the display panel of the display apparatus of Comparative Example 2A at the standard coordinates (0.1754, 0.1579) may deviate from the range of McAdams ellipse 10.

Referring to FIG. 9B, the angle-dependent color change of the display panel of the display apparatus of Comparative Example 2B at the standard coordinates (0.1754, 0.1579) may deviate from the required trajectory. The angle-dependent color change of the display panel of the display apparatus of Comparative Example 2B at the standard coordinates (0.1754, 0.1579) may deviate from the range of McAdams ellipse 10.

Referring to FIG. 9C, the angle-dependent color change of the display panel of the display apparatus of Comparative Example 2C at the standard coordinates (0.1754, 0.1579) may deviate from the required trajectory. The angle-dependent color change of the display panel of the display apparatus of Comparative Example 2C at the standard coordinates (0.1754, 0.1579) may deviate from the range of McAdams ellipse 10.

Referring to FIG. 9D, the angle-dependent color change of the display panel of the display apparatus of Experimental Example 2 at the standard coordinates (0.1754, 0.1579) may be located within the required trajectory range. In other words, the angle-dependent color change of the display panel of Experimental Example 2 at the standard coordinates (0.1754, 0.1579) may be located within the range of McAdams ellipse of about 10 or less. The display apparatus of Experimental Example 2 may include a color filter having a transmittance of about 0.5 or less at a second wavelength of more than about 460 nm, and a color change due to a viewing angle change with respect to blue light emitted from the display apparatus may not be observed by the human eyes.

According to embodiments, the user may not recognize a viewing angle-dependent color change of the display apparatus with respect to blue light and thus may equally recognize the colors seen from the front and side surfaces of the display apparatus. Thus, the display apparatus may have improved image characteristics.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope of the disclosure and as defined by the following claims.

What is claimed is:

1. A display apparatus comprising:
a light emitting device disposed over an emission area of a substrate, the light emitting device comprising a pixel electrode, an emission layer, and an opposite electrode; and
a display panel comprising a color filter disposed over the light emitting device, wherein
a transmittance of the color filter of light of a first wavelength is less than a transmittance of the color filter of light of a second wavelength and the transmittance of the color filter of light of the second wavelength is about 0.5 or less,
the first wavelength is in a range of about 380 nm to about 460 nm,
the second wavelength is in a range of about 460 nm to about 780 nm,
a wavelength-dependent transmittance graph of the color filter has a negative slope of less than about 0 at a wavelength of about 460 nm,
an emission spectrum of the display panel in the emission area of the substrate has a tristimulus value Z in a range of about 0.82 to about 1, and
an angle-dependent color change of the display panel in the emission area of the substrate at standard coordinates (0.1754, 0.1579) is within a MacAdams ellipse range of about 10 or less.

2. The display apparatus of claim 1, wherein a peak wavelength of the wavelength-dependent transmittance graph of the color filter is about 460 nm or less.

3. The display apparatus of claim 1, wherein the emission layer comprises a material emitting light of the first wavelength.

4. The display apparatus of claim 1, wherein
the pixel electrode comprises a lower transparent electrode, a metal electrode disposed over the lower transparent electrode, and an upper transparent electrode, and
the opposite electrode comprises a metal layer.

5. The display apparatus of claim 1, wherein
the emission layer comprises:
a first emission layer; and
a second emission layer disposed over the first emission layer and vertically spaced apart from the first emission layer, and
the light emitting device further comprises a first charge generation layer disposed between the first emission layer and the second emission layer.

6. The display apparatus of claim 5, wherein
the emission layer further comprises a third emission layer disposed between the second emission layer and the opposite electrode, and
the light emitting device further comprises a second charge generation layer disposed between the second emission layer and the third emission layer.

7. The display apparatus of claim 1, wherein the light emitting device further comprises:
a lower common layer disposed on a lower surface of the emission layer and comprising at least one of a hole transport layer and a hole injection layer; and
an upper common layer disposed on an upper surface of the emission layer and comprising at least one of an electron transport layer and an electron injection layer.

8. The display apparatus of claim 1, further comprising:
a first inorganic encapsulation layer disposed over the light emitting device;
an organic encapsulation layer disposed over the first inorganic encapsulation layer; and
a second inorganic encapsulation layer disposed over the organic encapsulation layer.

9. The display apparatus of claim 8, further comprising:
a touch sensor layer disposed over the second inorganic encapsulation layer,
wherein the color filter is disposed over the touch sensor layer.

10. The display apparatus of claim 9, further comprising:
a light blocking pattern disposed over the touch sensor layer and including an upper opening exposing an upper surface of the touch sensor layer,
wherein the color filter is disposed on the exposed upper surface of the touch sensor layer and in the upper opening of the light blocking pattern.

11. The display apparatus of claim 10, further comprising:
a cover window disposed over the color filter; and
a window adhesive layer disposed between the color filter and the cover window, the window adhesive layer comprising an optically clear adhesive.

12. The display apparatus of claim 11, further comprising:
a pixel circuit layer disposed over the substrate, the pixel circuit layer comprising a thin film transistor, wherein
the thin film transistor comprises a semiconductor layer, a gate electrode, a source electrode, and a drain electrode, and
the pixel electrode is electrically connected to the thin film transistor.

13. The display apparatus of claim 12, further comprising:
a buffer layer disposed between the substrate and the thin film transistor;
a gate insulating layer disposed between the semiconductor layer and the gate electrode; and
an interlayer insulating layer disposed over the gate electrode,
wherein the source electrode and the drain electrode are disposed on the interlayer insulating layer.

14. A display apparatus comprising:
a light emitting device disposed over an emission area of a substrate and emitting light of a first wavelength; and
a display panel comprising a color filter disposed over the light emitting device, wherein
a transmittance of the color filter of light of the first wavelength is less than a transmittance of the color filter of light of a second wavelength and the second wavelength is greater than the first wavelength, and
an angle-dependent color change of the display panel in the emission area of the substrate at standard coordinates (0.1754, 0.1579) is within a trajectory range of about 10 of a MacAdams ellipse.

15. The display apparatus of claim 14, wherein
the first wavelength comprises a visible light wavelength of about 460 nm or less, and
the second wavelength comprises a visible light wavelength of about 460 nm or more.

16. The display apparatus of claim 15, wherein
a wavelength-dependent transmittance graph of the color filter has a negative slope at a wavelength of about 460 nm, and
a peak wavelength of the wavelength-dependent transmittance graph of the color filter is less than about 460 nm.

17. The display apparatus of claim 14, wherein the light emitting device comprises a transparent pixel electrode, an emission layer disposed over the transparent pixel electrode, and a transparent opposite electrode.

18. The display apparatus of claim 17, wherein an emission spectrum of the display panel in the emission area of the substrate has a tristimulus value Z in a range of about 0.8 to about 1.

19. The display apparatus of claim 14, wherein
an emission spectrum of the display panel in the emission area of the substrate has a tristimulus value Z in a range of about 0.82 to about 1, and
the light emitting device comprises:
a pixel electrode comprising a lower transparent electrode, a metal electrode disposed over the lower transparent electrode, and an upper transparent electrode;
an emission layer disposed over the pixel electrode; and
an opposite electrode comprising a metal layer.

20. The display apparatus of claim 14, further comprising:
a thin film encapsulation layer disposed over the light emitting device and encapsulating the light emitting device.
